(19) United States
(12) Patent Application Publication
(10) Pub. No.: US 2026/0065954 A1
(43) Pub. Date: Mar. 5, 2026

(54) SEMICONDUCTOR DEVICE

(71) Applicant: Kioxia Corporation, Tokyo (JP)

(72) Inventors: Kousuke SUZUKI, Yokkaichi Mie (JP); Toshiyuki MORITA, Yokkaichi Mie (JP); Daichi NISHIKAWA, Mie Mie (JP)

(21) Appl. No.: 19/074,261

(22) Filed: Mar. 7, 2025

(30) Foreign Application Priority Data
Aug. 27, 2024 (JP) 2024-145916

(51) Int. Cl. G11C 5/06; H01L 23/00; H10B 41/20; H10B 43/20; H10D 64/66

(52) U.S. Cl. CPC G11C 5/063; H10B 41/20; H10B 43/20; H10D 64/665

(57) ABSTRACT

According to one embodiment, a semiconductor device that can prevent occurrence of defects is provided. A semiconductor device according to the present embodiment includes a wiring layer that includes a plurality of lines, and a columnar electrode that is integrally provided with the lines and extends from a bottom of one of the lines in a direction substantially perpendicular to the wiring layer. The lines include conductive films and a first film, the conductive and first films being alternately stacked in the direction substantially perpendicular to the wiring layer.

### CROSS-REFERENCE TO RELATED APPLICATION(S)

This application is based upon and claims the benefit of priority from Japanese Patent Application No. 2024-145916, filed Aug. 27, 2024, the entire contents of which are incorporated herein by reference.

### FIELD

Embodiments described herein relate generally to a semiconductor device.

### BACKGROUND

Lines of semi-damascene wiring or the like are formed by processing a film formed by CVD (chemical vapor deposition), for example. There is a possibility that the roughness of a surface of the film formed by CVD causes concavity defects in the lines.

### BRIEF DESCRIPTION OF THE DRAWINGS

FIG. 1 is a sectional view showing an example of a configuration of a wiring layer in a semiconductor device according to a first embodiment.

FIG. 2A is a sectional view of the wiring layer during a method of manufacturing the semiconductor device according to the first embodiment.

FIG. 2B is a sectional view of the wiring layer during the method of manufacturing the semiconductor device subsequent to FIG. 2A.

FIG. 3A is a sectional view of the wiring layer during the method of manufacturing the semiconductor device according to the first embodiment.

FIG. 3B is a sectional view of the wiring layer during the method of manufacturing the semiconductor device subsequent to FIG. 3A.

FIG. 3C is a sectional view of the wiring layer during the method of manufacturing the semiconductor device subsequent to FIG. 3B.

FIG. 3D is a sectional view of the wiring layer during the method of manufacturing the semiconductor device subsequent to FIG. 3C.

FIG. 3E is a sectional view of the wiring layer during the method of manufacturing the semiconductor device subsequent to FIG. 3D.

FIG. 4 is a sectional view of a wiring layer a method of manufacturing a semiconductor device according to a first comparative example.

FIG. 5 is a graph showing an example of the relationship between the film thickness of a conductive film and occurrence of defects in lines according to the first embodiment and the first comparative example.

FIG. 6A is a sectional view of the wiring layer during the method of manufacturing the semiconductor device according to the first comparative example.

FIG. 6B is a sectional view of the wiring layer during the method of manufacturing the semiconductor device subsequent to FIG. 6A.

FIG. 6C is a sectional view of the wiring layer during the method of manufacturing the semiconductor device subsequent to FIG. 6B.

FIG. 6D is a sectional view of the wiring layer during the method of manufacturing the semiconductor device subsequent to FIG. 6C.

FIG. 6E is a sectional view of the wiring layer during the method of manufacturing the semiconductor device subsequent to FIG. 6D.

FIG. 7 is a sectional view of a wiring layer during a method of manufacturing a semiconductor device according to a second comparative example.

FIG. 8 is a sectional view showing an example of a structure of a semiconductor device according to a fourth embodiment.

### DETAILED DESCRIPTION

A semiconductor device that can prevent occurrence of defects is provided.

In general, according to one embodiment, a semiconductor device of the present embodiment includes a wiring layer that includes a plurality of lines, and a columnar electrode that is integrally provided with the lines and extends from a bottom of one of the lines in a direction substantially perpendicular to the wiring layer. The lines include conductive films and a first film, the conductive and first films being alternately stacked in the direction substantially perpendicular to the wiring layer.

Hereinafter, referring to the drawings, embodiments according to the present invention are described. The present embodiments do not limit the present invention. The drawings are schematic or conceptual. The scale and the like of each component are not necessarily identical to actual ones. In the specification and drawings, elements similar to those described with reference to the drawings that have already been referred to are assigned the same symbols, and detailed description of them is appropriately omitted.

### First Embodiment

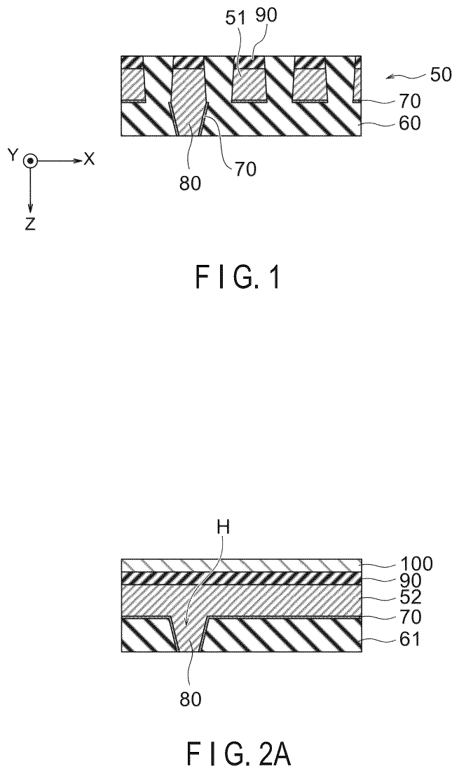

FIG. 1 is a sectional view showing an example of a configuration of a semiconductor device according to a first embodiment. FIG. 1 shows a wiring layer 50 used in the semiconductor device.

The semiconductor device includes the wiring layer 50, an insulating layer 60, a barrier metal film 70, a columnar electrode (via plug) 80, and an insulating film 90.

The wiring layer 50 is provided on an XY plane. The wiring layer 50 includes a plurality of lines 51 in the same layer. In a case where the semiconductor device is a memory (storage element), the wiring layer 50 includes, for example, lines for a memory cell array, and lines for peripheral circuits, such as electric circuits. Hereinafter, the case where the semiconductor device is a memory is described. However, there is no limitation to this. The semiconductor device may be a logic circuit (logic element) or the like.

The lines 51 are arranged in a predetermined pattern, for example. The lines 51 are arranged in a line and space pattern, for example. The lines 51 extend in the direction (Y direction) perpendicular to the sheet of FIG. 1. The lines 51 are arranged side by side in the X direction. The lines 51 are used as, for example, bit lines of the memory.

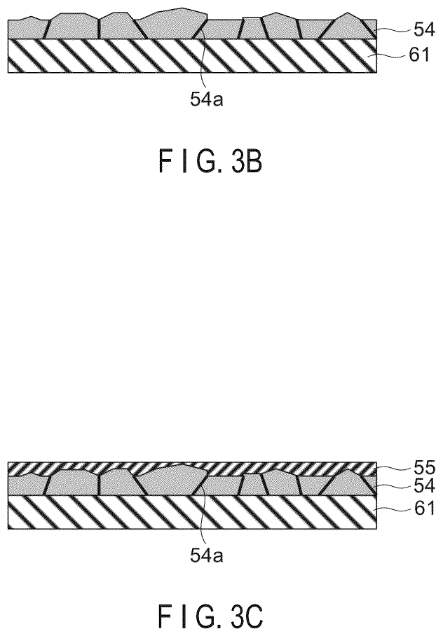

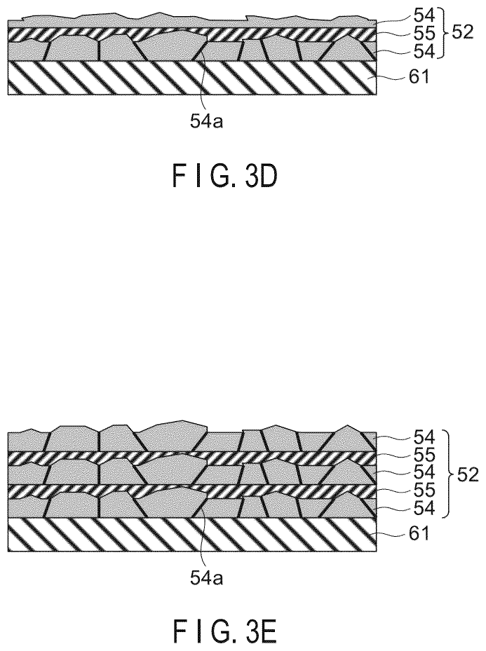

For example, a conductive material, such as tungsten (W), is used as the material of the lines 51. Note that the details of the configuration of lines 51 are described later with reference to FIGS. 3A to 3E.

The insulating layer 60 insulates lines 51 from each other. For example, SiO₂ is used as the material of the insulating layer 60. The insulating layer 60 is formed using, for example, TEOS (tetraethoxysilane) or the like.

The barrier metal film 70 prevents W contained in the material of the lines 51 from being diffused. The barrier metal film 70 is provided between the lines 51 and the insulating layer 60. The barrier metal film 70 is provided between the columnar electrode 80 and the insulating layer 60. For example, titanium (Ti), Ta (tantalum), tantalum nitride film (TaN) or the like is used for the barrier metal film 70.

The columnar electrode 80 electrically connects the line 51 to a lower-layer line (not shown). The columnar electrode 80 is integrally provided with the line 51, and extends from the bottom of the line 51 in a direction (Z direction) substantially perpendicular to the wiring layer 50. The material of the columnar electrode 80 is the same as the material of the line 51. For example, a conductive material, such as tungsten (W), is used as the material of the columnar electrode 80.

The insulating film 90 is provided on the line 51. For example, SiN is used as the material of the insulating film 90.

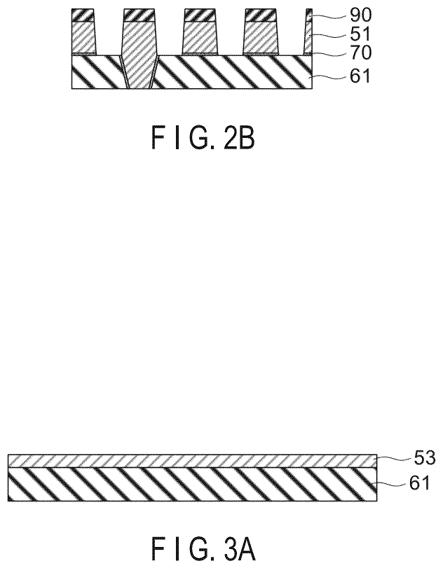

FIGS. 2A and 2B are sectional views of the wiring layer 50 during a method of manufacturing the semiconductor device according to the first embodiment.

First, as shown in FIG. 2A, a hole H is formed in an insulating film 61, a barrier metal film 70 is formed on the insulating film 61 and in the hole H, a line member 52 is formed so that the hole H is filled and this member is provided on the insulating film 61, the insulating film 90 is formed on the line member 52, and the semiconductor film 100 is formed on the insulating film 90. The line member 52 is formed by, for example, CVD (chemical vapor deposition). For example, amorphous silicon is used as the material of the semiconductor film 100.

Note that the line member 52 embedded in the hole H becomes the columnar electrode 80. That is, the columnar electrode 80 is formed simultaneously with the line member 52, which is to be lines 51 after processing.

The details of formation of the line member 52 are described later with reference to FIGS. 3A to 3E.

Next, as shown in FIG. 2B, processing the line member 52 forms the lines 51, which are arranged in a predetermined pattern. The processing of the line member 52 is performed by, for example, RIE (reactive-ion etching).

Subsequently, the gaps between the lines 51 are filled with an insulating film that is the same as the insulating film 61, and a polishing process (for example, CMP (chemical mechanical polishing)) is applied until the insulating film 90 is exposed, thereby completing the structure shown in FIG. 1.

Next, formation of the line member 52 is described.

FIGS. 3A and 3E are sectional views of the wiring layer 50 during the method of manufacturing a semiconductor device according to the first embodiment. Note that the barrier metal film 70 is omitted.

First, as shown in FIG. 3A, a nucleation layer 53 is formed on the insulating film 61. The nucleation layer 53 is formed by, for example, alternately supplying diborane (B₂H₆) gas and tungsten hexafluoride (WF₆) gas into a processing chamber, and performing processing.

Next, as shown in FIG. 3B, a conductive film 54 is formed. Metal crystal grains (growth nuclei) contained in the nucleation layer 53 grow and increase in particle diameter, thus forming the conductive film 54. The principal component of the conductive film 54 is, for example, tungsten (W). The conductive film 54 is formed, for example, by performing processing while supplying tungsten hexafluoride (WF₆) and hydrogen (H₂) gas into the processing chamber. The conductive film 54 is formed until its thickness becomes about 15 nm, for example. The thickness of the conductive film 54 is the thickness in the vertical direction (Z direction) perpendicular to the sheet. Note that as described later with reference to FIG. 5, the thickness of the conductive film 54 is determined in a range where no defect occurs in the lines 51. FIG. 3B shows crystal grain boundaries 54a of the conductive film 54.

Next, as shown in FIG. 3C, a film 55 is formed on the conductive film 54. The film 55 is an amorphous film. The film 55 is formed by, for example, diborane soaking. In this case, the film 55 is a film that contains diborane absorbed in the surface of the conductive film 54. The film 55 as a soaked film is formed by performing processing while supplying diborane gas into the processing chamber. Note that the upper surface of the film 55 shown in FIG. 3C is flat. However, the upper surface of the film 55 is not necessarily flat.

Next, as shown in FIG. 3D, a conductive film 54 is formed on the film 55. For example, similar to FIG. 3B, the conductive film 54 is formed until its thickness becomes about 15 nm.

Next, as shown in FIG. 3E, processing steps shown in FIGS. 3C and 3D are repetitively executed (cyclic film formation). The line member 52 is thus formed. In the example shown in FIG. 3E, three layers of conductive films 54 are formed.

The line member 52 includes conductive films 54 and films 55 that are alternately stacked in the direction (Z direction) substantially perpendicular to the wiring layer 50. Consequently, likewise, the lines 51 shown in FIG. 1 also include conductive films 54 and films 55 that are alternately stacked in the direction (Z direction) substantially perpendicular to the wiring layer 50. The principal component of the conductive film 54 is, for example, tungsten (W). The films 55 are of a film type different from that of the conductive films 54. In the first embodiment, the principal component of the films 55 is different from the principal component of the conductive films 54, and is boron (B). The number of stacks of the conductive films 54 and the films 55 is, for example, two or more. For example, in a case where the line member 52 is formed to have a thickness of 40 nm, three layers of conductive films 54 each having about 13 nm are formed.

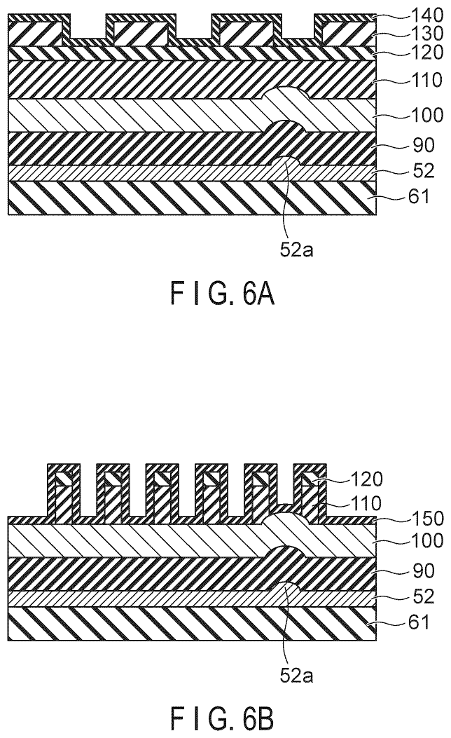

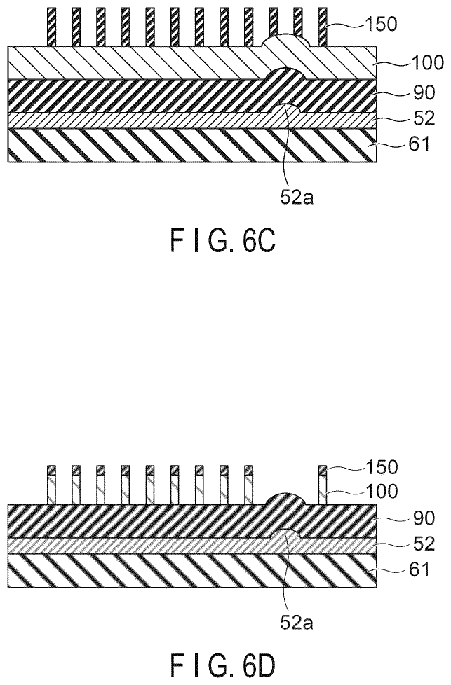

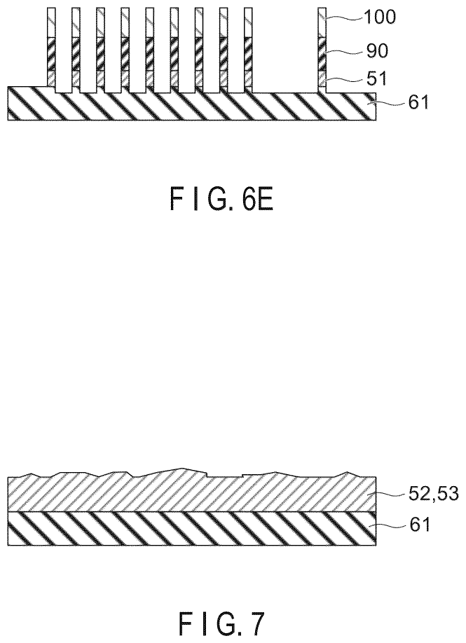

Each film 55 that is an auxiliary film functions as a division film provided between two conductive films 54 sandwiching the film 55 so as to divide the crystal grains of the conductive films 54. Each film 55 can stop the growth of the crystal grains in the conductive film 54, and let the particle diameter in the conductive film 54 equal to or less than a predetermined particle diameter. This can prevent the conductive film 54 from having a large particle diameter, and can reduce (improve) the roughness of the surface of the line member 52. As a result, occurrence of defects in the lines 51 in steps of processing the line member 52 can be prevented. Note that details of defects of the lines 51 caused by the roughness of the surface of the line member 52 are described later with reference to FIGS. 6A to 6E.

Each film 55 is formed until it covers the corresponding conductive film 54 and has a thickness capable of appropriately dividing the crystallizability of the conductive film 54. Consequently, the film 55 may be thinner than the conductive film 54. Since the film 55 is a soaked film, the film 55 is formed only by letting diborane absorbed by the surface of the conductive film 54. The soaked film containing diborane is used as a reduction agent when the conductive film 54 is formed. Accordingly, the film 55 is allowed to be much thinner. Consequently, the ratio of the thickness of the conductive film 54 to the thickness of the entire line member 52 can be increased. As a result, the wiring resistance of the lines 51 can be further reduced.

As described above, according to the first embodiment, the lines 51 include the conductive films 54 and the films 55 that are alternately stacked in the direction (Z direction) substantially perpendicular to the wiring layer 50. Note that the lines 51 include at least two layers of conductive films 54. This can prevent the conductive film 54 from having a large particle diameter, and can reduce (improve) the roughness of the surface of the line member 52. As a result, defects in the lines 51 can be prevented. The larger the surface irregularity of the line member 52 (see FIG. 5) is, that is, the higher the convexes on the upper surface of the line member 52 from a reference surface are, the larger the roughness is.

As shown in FIG. 2A, the line member 52 and the columnar electrode 80 can be integrally formed at the same time by CVD. Accordingly, the number of processing steps can be reduced.

The insulating films 90 are provided on the lines 51. The insulating films 90 are arranged depending on the shapes of the lines 51 viewed from the direction (Z direction) substantially perpendicular to the wiring layer 50. More specifically, the insulating films 90 are provided along the lines 51. For example, the outer edge shapes of the insulating films 90 may be substantially identical to the outer edge shapes of the lines 51 viewed from the direction (Z direction) substantially perpendicular to the wiring layer 50. When upper columnar electrodes (not shown) electrically connected to the upper parts of the lines 51 are formed, parts of the insulating films 90 on the lines 51 are recessed (processed), and a conductive material is embedded. Accordingly, the shapes of the bottoms of the upper part columnar electrodes can be adjusted, and for example, the bottoms of the upper part columnar electrodes can be positioned only at upper parts of the lines 51. As a result, concerns about pressure resistance can be reduced.

Note that the films 55 are not limited to those in the example described above. Preferably, the films 55 are films that can be formed in the same chamber or the same apparatus.

### First Comparative Example

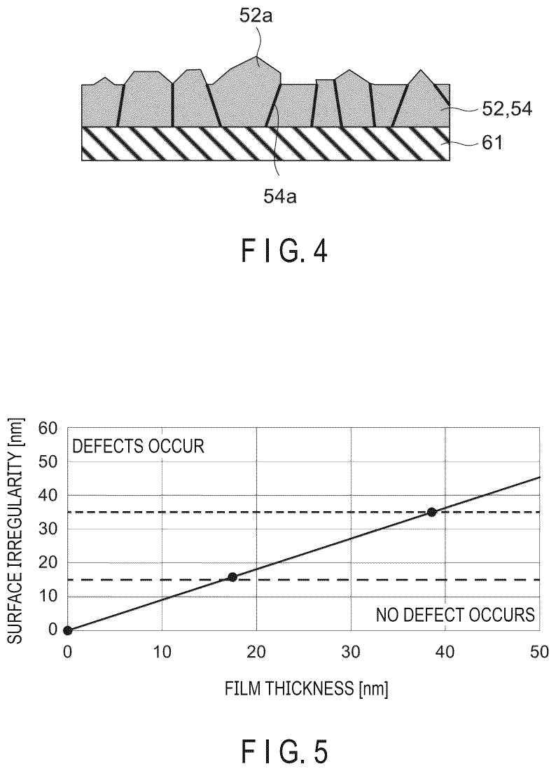

FIG. 4 is a sectional view of a wiring layer during a method of manufacturing a semiconductor device according to a first comparative example. The first comparative example is different from the first embodiment in that no film 55 is provided and the conductive film 54 continuously grows.

In the first comparative example, the processing step shown in FIG. 3B in the first embodiment is continuously performed, and a line member 52 that includes a conductive film 54 having a large particle diameter is formed. As the particle diameter in the conductive film 54 is larger, the specific resistance of the lines 51 reduces, which can reduce the wiring resistance of the lines 51. However, as the particle diameter in the conductive film 54 is larger, the roughness of the surface of the line member 52 is degraded. In the example shown in FIG. 4, local convexes occur on the upper surface of the line member 52. The convex 52a shown in FIG. 4 is a convex having the largest height difference.

FIG. 5 is a graph showing an example of the relationship between the film thickness of a conductive film 54 and occurrence of defects in lines 51 according to the first embodiment. The abscissa axis of the graph indicates the film thickness of the conductive film 54. The ordinate axis of the graph indicates the surface irregularity. The surface irregularity is the maximum value of the height difference of the local convex that occurs on the upper surface of the line member 52 (in the example shown in FIG. 4, the height difference of the convex 52a shown in FIG. 4).

In the case where the film thickness of the conductive film 54 is about 38 nm or more (as in the first comparative example), the surface irregularity of the line member 52 is about 35 nm or more, and there is a possibility that defects occurs in the lines 51.

On the other hand, in the case where the thickness of the conductive film 54 is about 15 nm or less (as in the first embodiment), the surface irregularity of the line member 52 is about 15 nm or less, and no defect occurs in the lines 51. When the conductive film 54 is formed on the film 55, the conductive film 54 grows from a state where the thickness of the conductive film 54 in the abscissa axis of the graph is reset to zero nm. Accordingly, even if the total thickness of the conductive film 54 is large, the roughness of the surface of the line member 52 can be reduced.

Next, defects are described.

FIGS. 6A to 6E are sectional views of a wiring layer during a method of manufacturing a semiconductor device according to the first comparative example.

FIG. 6A shows the line member 52 described with reference to FIG. 4. As shown in FIG. 6A, on the upper surface of the line member 52, a local convex 52a due to the roughness of the surface occurs. Due to the convex 52a, convexes similarly occur also on the upper surfaces of the insulating film 90 and the semiconductor film 100, which are on the convex 52a.

First, as shown in FIG. 6A, an insulating film 90, a semiconductor film 100 as a mask film, a mask film 110, and an insulating film 120 are formed on the line member 52 in this order, resists 130 are formed in predetermined regions on the insulating film 120, and a spacer 140 is formed on the insulating film and the resists 130.

The insulating film 120 is, for example, an SOG (spin on glass) film. The spacer 140 contains, for example, SiO₂.

Next, as shown in FIG. 6B, the mask film 110, the insulating film 120, the resists 130, and the spacer 140 are processed until the semiconductor film 100 is exposed, thus forming spacers 150. The processing is performed by, for example, RIE.

Next, as shown in FIG. 6C, the mask film 110, the insulating film 120, and the spacers 150 are processed. The processing is performed by, for example, RIE/WET or the like. As shown in FIG. 6C, spacers 150 provided above the convex 52a are shorter than spacers 150 provided at other positions.

Next, as shown in FIG. 6D, the spacers 150 are used as masks, and the semiconductor film 100 is processed. Processing of the semiconductor film 100 is performed by, for example, RIE. As shown in FIG. 6D, the spacers 150 provided above the convex 52a completely disappear during processing. Since the spacers 150 as the masks disappear, the semiconductor film 100 above the convex 52a also disappears.

Next, as shown in FIG. 6E, the spacers 150 are used as masks, the line member 52 is processed. By processing the line member 52, the lines 51 arranged in a predetermined pattern, such as a line and space pattern, are formed. Note that the processing step shown in FIG. 6D and the processing step shown in FIG. 6E are continuously performed. As shown in FIG. 6E, due to disappearance of the spacers 150 as the masks, the lines 51 are not formed at a position where the convex 52a occurs. That is, concavity defects in the lines 51 occur.

On the other hand, according to the first embodiment, cyclic film formation of the conductive film 54 and the film 55 can prevent the conductive film 54 from having a large particle diameter, and advantageously reduce the roughness on the surface of the line member 52. As a result, occurrence of the convex 52a can be prevented, which can prevent defects in the lines 51.

Note that the thickness of the conductive film 54 is determined, for example, by obtaining the relationship between the film thickness of the conductive film 54 and occurrence of defects in the lines 51 shown in FIG. 5 through an experiment.

### Second Comparative Example

FIG. 7 is a sectional view of a wiring layer during a method of manufacturing a semiconductor device according to a second comparative example. The second comparative example is different from the first embodiment in that the entire line member 52 is made up of the nucleation layer 53.

According to the second comparative example, the processing step shown in FIG. 3A in the first embodiment is continuously performed. The nucleation layer 53 is amorphous. Consequently, the roughness of the surface of the line member 52 is advantageously reduced in comparison with the first comparative example. However, the specific resistance of the lines 51 becomes high. As a result, the wiring resistance of the lines 51 becomes high.

In contrast, according to the first embodiment, the conductive films 54 having particle diameters to a certain extent are formed. Accordingly, the specific resistance of the lines 51 can be made low. As a result, the line member 52 that has a low resistance and an advantageously reduced surface roughness can be formed.

### Second Embodiment

A second embodiment is different from the first embodiment in that the film 55 is an oxide film.

The principal component of the film 55 is an oxide of a metal element that is the principal component of the conductive film 54.

The film 55 as the oxide film is formed, for example, by oxidizing the surface of the conductive film 54. Since the conductive film 54 contains tungsten (W), the film 55 contains WO as the principal component. Note that the film 55 is an amorphous film.

Since the film 55 is the oxide film, the film 55 can be more easily formed.

If tungsten hexafluoride and hydrogen gas are supplied onto WOₓ, WOₓ is reduced and the film 55 is thinned in some cases. In such cases, the ratio of the thickness of the conductive film 54 to the thickness of the entire line member 52 can be increased. As a result, the wiring resistance of the lines 51 can be further reduced.

Also in this case, advantageous effects similar to those of the first embodiment can be achieved.

### Third Embodiment

A third embodiment is different from the first embodiment in that the film 55 is a nucleation layer for the conductive film 54.

The principal component of the film 55 is the same as the principal component of the conductive film 54. More specifically, the film 55 is a nucleation layer for the conductive film 54.

The film 55 as the nucleation layer is formed similarly to the nucleation layer 53 in the processing step shown in FIG. 3A, for example. In this case, the film 55 is a tungsten film that contains much diborane that is a material gas for forming the nucleation layer. Consequently, the film 55 contains boron (B) based on diborane. Note that the film 55 is an amorphous film.

Since the film 55 is a metal film, the resistance is relatively low. Consequently, the wiring resistance of the lines 51 can be further reduced.

Also in this case, advantageous effects similar to those of the first embodiment can be achieved.

### Fourth Embodiment

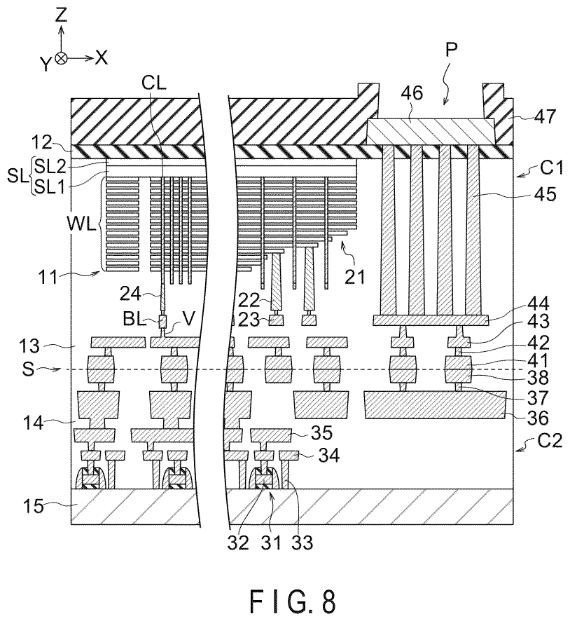

FIG. 8 is a sectional view showing an example of a structure of a semiconductor device according to a fourth embodiment. The semiconductor device shown in FIG. 8 is a three-dimensional memory where an array chip C1 and a circuit chip C2 are bonded together.

The array chip C1 includes: a memory cell array 11 that includes three-dimensionally arranged memory cells; an insulating film 12 above the memory cell array 11; and an inter-layer insulating film 13 below the memory cell array 11. The insulating film 12 is, for example, a silicon oxide film or a silicon nitride film. The inter-layer insulating film 13 is, for example, a silicon oxide film, or a film stack that includes a silicon oxide film and another insulating film.

The circuit chip C2 is provided under the array chip C1. Symbol S denotes a pasting surface between the array chip C1 and the circuit chip C2. The circuit chip C2 includes an inter-layer insulating film 14, and a substrate 15 under the inter-layer insulating film 14. The inter-layer insulating film 14 is, for example, a silicon oxide film, or a film stack that includes a silicon oxide film and another insulating film. The substrate 15 is an example of a first substrate, and is, for example, a semiconductor substrate, such as a silicon substrate. FIG. 8 shows an X direction and a Y direction that are parallel to a surface, or the upper surface, of the substrate 15 and are perpendicular to each other, and a Z direction that is perpendicular to the surface of the substrate 15. The Y direction is an example of a first direction. The X direction is an example of a second direction that intersects the first direction. The Z direction is an example of a third direction that intersects the first and second directions.

The array chip C1 includes word lines WL and source lines SL, as electrode layers in the memory cell array 11. FIG. 8 shows a step structure 21 of the memory cell array 11. Each word line WL is electrically connected to a word wiring layer 23 via a contact plug 22. Each columnar portion CL penetrating through the word lines WL is electrically connected to a bit line BL through a via plug 24, and electrically connected to the source lines SL. The source lines SL include a first layer SL1 that is a semiconductor layer, and a second layer SL2 that is a metal layer. Symbol V denotes a via plug provided under the bit line BL.

The circuit chip C2 includes a plurality of transistors 31. Each transistor 31 includes: a gate electrode 32 provided on the substrate 15 via a gate insulating film; and a source diffusion layer and a drain diffusion layer that are provided in the substrate 15 but are not shown. The circuit chip C2 includes: a plurality of contact plugs 33 provided on the source diffusion layers or the drain diffusion layers of these transistors 31; a wiring layer 34 that includes a plurality of lines and is provided on these contact plugs 33; and a wiring layer 35 that includes a plurality of lines and is provided above the wiring layer 34.

The circuit chip C2 further includes: a wiring layer 36 that includes a plurality of lines and is provided above the wiring layer 35; a plurality of via plugs 37 provided on the wiring layer 36; and a plurality of metal pads 38 provided on these via plugs 37. The metal pad 38 is, for example, a Cu (copper) layer or an Al (aluminum) layer. The circuit chip C2 functions as a control circuit (logic circuit) that controls the operation of the array chip C1. The control circuit is made up of the transistors 31 and the like, and is electrically connected to the metal pads 38.

The array chip C1 includes: a plurality of metal pads 41 provided on the respective metal pads 38; and a plurality of via plugs 42 provided on the respective metal pads 41. The array chip C1 includes: a wiring layer 43 that includes a plurality of lines and is provided on these via plugs 42; and a wiring layer 44 that includes a plurality of lines including bit lines BL and is provided above the wiring layer 43. The metal pad 41 is, for example, a Cu layer or an Al layer. The via plug V described above is connected to the wiring layer 43 and the bit line BL.

The array chip C1 further includes: a plurality of via plugs 45 provided on the wiring layer 44; a metal pad 46 provided on these via plugs 45 and the insulating film 12; and a passivation layer 47 provided on the metal pad 46 and the insulating film 12. The metal pad 46 is, for example, a Cu layer or an Al layer, and functions as an external connection pad (bonding pad) of the semiconductor device in FIG. 8. The passivation layer 47 is, for example, an insulating film, such as a silicon oxide film, and has an opening P that allows the upper surface of the metal pad 46 to be exposed. The metal pad 46 is connected to a mounting board or another device, with bonding wires, solder balls, metal bumps, or the like via the opening P.

Here, the lines 51 in the wiring layer 50 described in the first to third embodiments correspond to, for example, the lines in the wiring layer 44. Note that FIG. 8 is vertically inverted relative to FIG. 1.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device comprising:
a wiring layer that includes a plurality of lines, and
a columnar electrode that is integrally provided with the lines and extends from a bottom of one of the lines in a direction substantially perpendicular to the wiring layer, wherein
the lines include conductive films, and a first film different from the conductive films, the conductive and first films being alternately stacked in the direction substantially perpendicular to the wiring layer.

2. The semiconductor device of claim 1, wherein the first film is provided between the two conductive films that sandwich the first film so as to divide crystal grains in the conductive films.

3. The semiconductor device of claim 1, wherein a principal component of the first film is different from a principal component of the conductive films.

4. The semiconductor device of claim 3, wherein the principal component of the first film is boron (B).

5. The semiconductor device of claim 3, wherein the principal component of the first film is an oxide of a metal element that is the principal component of the conductive films.

6. The semiconductor device of claim 1, wherein a principal component of the first film is identical to a principal component of the conductive films.

7. The semiconductor device of claim 6, wherein the first film is a nucleation layer for the conductive films.

8. The semiconductor device of claim 7, wherein the first film contains boron (B).

9. The semiconductor device of claim 1, wherein the first film is an amorphous film.

10. The semiconductor device of claim 1, wherein a principal component of the conductive films is tungsten (W).

11. The semiconductor device of claim 1, wherein the number of stacks, each stack including one of the conductive films and the first film, is two or more.

12. The semiconductor device of claim 1, wherein a thickness of the conductive film in the direction substantially perpendicular to the wiring layer is 15 nm or less.

13. The semiconductor device of claim 1, further comprising an insulating film provided on the lines, wherein
the insulating film is arranged based on shapes of the lines viewed from the direction substantially perpendicular to the wiring layer.

14. The semiconductor device of claim 1, further comprising:
a memory cell array; and
a plurality of columnar portions that penetrate through the memory cell array, wherein the lines are electrically connected to the respective columnar portions.

15. A semiconductor device comprising a wiring layer that includes a plurality of lines, wherein:
the lines include conductive films and first films different from the conductive films, the conductive and first films being alternately stacked in a direction substantially perpendicular to the wiring layer,
a principal component of the first films is different from a principal component of the conductive films, and
the number of the conductive films and the first films is five or more.

16. The semiconductor device of claim 15, wherein
the principal component of the first film is boron (B), or an oxide of a metal element that is the principal component of the conductive films, or
the first film is an amorphous film.

17. The semiconductor device of claim 15, wherein a thickness of the conductive film in the direction substantially perpendicular to the wiring layer is 15 nm or less.

18. A semiconductor device comprising:
a wiring layer that includes a plurality of lines, and
a columnar electrode that is integrally provided with the lines and extends from a bottom of one of the lines in a direction substantially perpendicular to the wiring layer, wherein
the lines include conductive films and a first film different from the conductive films, the conductive and first films being alternately stacked in the direction substantially perpendicular to the wiring layer, and
a principal component of the first film is identical to a principal component of the conductive films or the first film is an amorphous film.

19. The semiconductor device of claim 18, wherein the first film is a nucleation layer for the conductive films in the case of the principal component of the first film being identical to the principal component of the conductive films.

20. The semiconductor device of claim 19, wherein the first film contains boron (B) in the case of the principal component of the first film being identical to a principal component of the conductive films.
